(19) United States
(12) Patent Application Publication
(10) Pub. No.: US 2015/0068579 A1
(43) Pub. Date: Mar. 12, 2015

(54) Multilayer back electrode for a photovoltaic thin-film solar cell, use thereof for manufacturing thin-film solar cells and modules, photovoltaic thin-film solar cells and modules containing the multilayer back electrode and a manufacturing method

(71) Applicant: Volker Probst, Berlin (DE)

(72) Inventor: Volker Probst, Berlin (DE)

(73) Assignee: Robert Bosch GmbH, Stuttgart (DE)

(21) Appl. No.: 14/389,894

(22) PCT Filed: Feb. 19, 2013
(86) PCT No.: PCT/EP2013/053224

§ 371 Date: Oct. 1, 2014

(30) Foreign Application Priority Data
Apr. 2, 2012 (DE) 10 2012 205 375.1

(51) Int. Cl. H01L 31/0224; H01L 31/02; H01L 31/032

(52) U.S. Cl. CPC H01L 31/022441; H01L 31/0322; H01L 31/02008
USPC 136/244; 136/256; 438/98

(57) ABSTRACT

A multilayer back electrode for a photovoltaic thin-film solar cell includes, in the following sequence: at least one bulk back electrode layer containing at least one of V, Mn, Cr, Mo, Co, Zr, Ta, Nb, and W; at least one conductive barrier layer; and at least one ohmic contact layer containing (i) at least one first ply adjacent to the at least one conductive barrier layer, the at least one first ply containing at least one of Mo, W, Ta, Nb, Zr and Co, and (ii) at least one second ply not adjacent to the at least one barrier layer, the at least one second ply containing at least one metal chalcogenide.

### BACKGROUND OF THE INVENTION

1. Field of the Invention

The present invention relates to a multilayer back electrode for a photovoltaic thin-film solar cell, the use of this multilayer back electrode for manufacturing thin-film solar cells and thin-film solar modules, photovoltaic thin-film solar cells and solar modules containing the multilayer back electrode according to the present invention, and a method for manufacturing photovoltaic thin-film solar cells and solar modules.

2. Description of the Related Art

Suitable photovoltaic solar modules include, on the one hand, crystalline and amorphous silicon solar modules and, on the other hand, so-called thin-film solar modules. In the latter, in general an IB-IIIA-VIA connection semiconductor layer, a so-called chalcopyrite semiconductor absorber layer, is used. In these thin-film solar modules, a molybdenum back electrode layer is typically applied to a glass substrate. In one method variant, this back electrode layer is provided with a precursor metal thin film, which contains copper and indium and also optionally gallium, and is subsequently reacted in the presence of hydrogen sulfide and/or hydrogen selenide at elevated temperatures to form a so-called CIS or CIGS system.

To be able to reliably achieve an acceptable efficiency, particular care is generally already necessary during the selection and production of the back electrode layer. For example, the back electrode layer is to have a high transverse conductivity, to ensure a low-loss series interconnection. Substances which migrate out of the substrate and/or the semiconductor absorber layer should not have any influence on the quality and functional range of the back electrode layer. In addition, the material of the back electrode layer must have good adaptation to the thermal expansion behavior of the substrate and the layers lying above it, to avoid micro-cracks. Finally, the adhesion on the substrate surface should also meet all common usage requirements.

It is possible to achieve good efficiencies via the use of particularly pure back electrode material; however, disproportionately high production costs generally accompany this. In addition, the above-mentioned migration phenomena, in particular diffusion phenomena, under the typical production conditions commonly result in significant contamination of the back electrode material.

A solar cell having an absorber layer which is well implemented with regard to morphology and has good efficiency is achieved according to published German patent document DE 44 42 824 C1 in that the chalcopyrite semiconductor absorber layer is doped using an element from the group sodium, potassium, and lithium in a dose of 10¹⁴ to 10¹⁶ atoms/cm² and at the same time a diffusion barrier layer is provided between the substrate and the semiconductor absorber layer. Alternatively, it is provided that an alkali-free substrate is used, if a diffusion barrier layer is to be omitted.

Blösch et al. (Thin Solid Films, 2011) provide for using a layer system made of titanium, titanium nitride, and molybdenum if a polyimide substrate film is used, to obtain good adhesion properties and a satisfactory thermal property profile. Blösch et al. (IEEE, 2011, volume 1, issue 2, pages 194 through 199) furthermore provide for the use of flexible thin-film solar cells, the usage of a stainless steel substrate film, on which a thin titanium layer is initially applied for the purpose of improving the adhesion. Satisfactory results were achieved using such CIGS thin-film solar cells, which were equipped with a titanium/molybdenum/molybdenum triple ply. Improved thin-film solar cells are also sought with the teaching of published international patent application document WO 2011/123869 A2. The solar cell disclosed therein includes a sodium glass substrate, a molybdenum back electrode layer, a CIGS layer, a buffer layer, a layer made of intrinsic zinc oxide, and a layer made of zinc oxide doped with aluminum. A first separating trench extends over the molybdenum layer, the CIGS layer, and the powder layer; a second separating trench begins above the molybdenum layer. An insulating material is deposited in or on the first separating trench, and a front electrode layer is to be deposited diagonally onto the solar cell, including the first separating trench. In this way, thin-film solar cells having improved light yield are to be obtained. US patent application publication number 2004/014419 A1 is concerned with providing a thin-film solar cell, the molybdenum back electrode layer of which has improved efficiency. This is to be achieved in that a glass substrate is provided with a back electrode layer made of molybdenum, the thickness of which is not to exceed 500 nm.

It is already found in Orgassa et al. (Thin Solid Films, 2003, volumes 431-432, pages 1987 through 1993) that greatly varying metals such as tungsten, molybdenum, chromium, tantalum, niobium, vanadium, titanium, and manganese come into question as suitable back electrode materials for thin-film solar cells.

Therefore, the present invention is based on the object of providing back electrode systems for thin-film solar cells or solar modules, which are no longer subject to the disadvantages of the related art and which, in particular in a cost-effective and reliable way, are reproducible as thin-film solar modules having high efficiencies.

Accordingly, a multilayer back electrode for a photovoltaic thin-film solar cell or photovoltaic module has been found, including, in this sequence, at least one bulk back electrode layer containing or essentially being formed of V, Mn, Cr, Mo, Co, Zr, Ta, Nb, and/or W and/or containing or essentially being formed from alloys containing V, Mn, Cr, Mo, Co, Zr, Fe, Ni, Al, Ta, Nb, and/or W; at least one conductive barrier layer;

at least one, in particular ohmic, contact layer,
containing or essentially being formed of Mo, W, Ta, Nb, Zr and/or Co, in particular Mo and/or W,
and/or
containing or essentially being formed of at least one metal chalcogenide,
and/or
containing at least one first ply, adjacent to the barrier layer, containing or essentially being formed of Mo, W, Ta, Nb, Zr and/or Co, in particular Mo and/or W, and at least one second ply, not adjacent to the barrier layer, i.e., separated from the barrier layer by the first ply, containing or being essentially formed of at least one metal chalcogenide.

According to one preferred embodiment, it may be provided that the bulk back electrode and the contact layer contain molybdenum or tungsten or a molybdenum or tungsten alloy, in particular molybdenum or a molybdenum alloy, or are essentially formed from molybdenum or tungsten or a molybdenum or tungsten alloy, in particular molybdenum or a molybdenum alloy.

Furthermore it may be provided that the barrier layer represents a barrier for components which migrate, in particular diffuse or are diffusible, out of the and/or via the bulk back electrode layer, and/or for components which migrate, in particular diffuse or are diffusible out of the and/or via the contact layer. The barrier layer thus preferably represents a bidirectionally acting barrier. In this context it may also be advantageously provided that the barrier layer represents a barrier for alkali ions, in particular sodium ions, selenium or selenium compounds, sulfur or sulfur compounds, metals, in particular Cu, In, Ga, Fe, Ni, Ti, Zr, Hf, V, Nb, Ta, Al, and/or W, and/or compounds containing alkali ions, for example sodium ions. In one particularly advantageous embodiment, it is provided that the barrier layer contains or is essentially formed of at least one metal nitride, in particular TiN, MoN, TaN, ZrN, and/or WN, at least one metal carbide, at least one metal boride, and/or at least one metal silicon nitride, in particular TiSiN, TaSiN, and/or WSiN. The metal of the metal nitrides, metal silicon nitrides, metal carbides, and/or metal borides preferably represents titanium, molybdenum, tantalum, or tungsten. Such metal nitrides are preferred as barrier materials in the meaning of the present invention, for example, TiN, in which the metal is deposited, with regard to nitrogen, stoichiometrically or super stoichiometrically, i.e., having nitrogen in excess.

The conductive barrier layer represents, as a bidirectionally acting barrier layer, a barrier for components, in particular dopants, which migrate, in particular diffuse or are diffusible, from the and/or via the back electrode layer and for components, in particular dopants, which diffuse or are diffusible from the and/or via the contact layer, in particular from the semiconductor absorber layer. Due to the circumstance of the presence of a barrier layer, it is possible, for example, to significantly reduce the degree of purity of the bulk back electrode material. For example, the bulk back electrode layer may be contaminated with at least one element selected from the group including Fe, Ni, Ti, Zr, Hf, V, Nb, Ta, Al, W, and/or Na and/or with compounds of the mentioned elements, without the efficiency of the thin-film solar cell or the solar module having the back electrode according to the present invention being disadvantageously impaired.

A further advantage of the use of a barrier layer with the multilayer back electrodes according to the present invention is manifested upon use in thin-film solar cells and solar modules in that the thickness of the semiconductor absorber layer, for example, the chalcopyrite or kesterite layer, may be significantly reduced in relation to conventional systems. This is because the sunlight passing the semiconductor absorber layer is very effectively reflected by the barrier layer, in particular if it is provided in the form of metal nitrides, for example, titanium nitride, or containing such metal nitrides or titanium nitrides, so that a very good quantum yield may be achieved in the course of the double passage through the semiconductor absorber layer. Due to the presence of the mentioned barrier layer in the back electrode according to the present invention or in thin-film solar cells or solar modules containing this back electrode, the average thickness of the semiconductor absorber layer may be reduced, for example, to values in the range of 0.4 μm to 1.5 μm, for example, to values in the range of 0.5 μm to 1.2 μm.

The barrier layer of the back electrode according to the present invention has, in one particularly advantageous embodiment, barrier properties, in particular bidirectional barrier properties, in relation to dopants, in particular in relation to dopants for the semiconductor absorber layer and/or from the semiconductor absorber layer, in relation to chalcogens such as selenium and/or sulfur and chalcogen compounds, in relation to the metallic components of the semiconductor absorber layer such as Cu, In, Ga, Sn, and/or Zn, in relation to contaminants such as iron and/or nickel from the bulk back electrode layer and/or in relation to components and/or contaminants from the substrate. The bidirectional barrier properties in relation to dopants from the substrate are to prevent, on the one hand, enrichment at the interface of the back electrode or contact layer to the semiconductor absorber layer with alkali ions, for example, diffusing out of a glass substrate. Such enrichments are known to be a reason for semiconductor layer detachments. The conductive barrier layer should therefore help to avoid adhesion problems. On the other hand, the barrier property of the dopants, diffusible or diffusing out of the semiconductor absorber, should prevent the dopant from being lost in this way to the bulk back electrode and therefore the semiconductor absorber from becoming deficient in the dopant, which would significantly reduce the efficiency of the solar cell or the solar module. This is because it is known, for example, that molybdenum back electrodes may absorb significant amounts of sodium dopant. The bidirectionally conductive barrier layer should therefore enable the requirements for suitable dosing of the dopant into the semiconductor absorber layer, to be able to achieve reproducible high efficiencies of the solar cells and solar modules.

The barrier property in relation to chalcogens should prevent them from reaching the back electrode and forming metal chalcogenide compounds therein. These chalcogenide compounds, for example, MoSe, are known to contribute to a substantial volume enlargement of the surface-proximal layer of the back electrode, which in turn results in irregularities in the layer structure and worsened adhesion. Contaminants of the bulk back electrode material such as Fe and Ni represent so-called deep imperfections for chalcopyrite semiconductors (semiconductor poisons) and are accordingly to be kept away from the semiconductor absorber layer via the barrier layer.

Furthermore, in one specific embodiment, it may be provided that the metal of the metal chalcogenide of the contact layer, or the second ply of the contact layer, is selected from molybdenum, tungsten, tantalum, zirconium, cobalt and/or niobium and that the chalcogenide of the metal chalcogen is selected from selenium and/or sulfur, the metal chalcogenide representing in particular MSe₂, MS₂ and/or M(Se₁₋ₓ,Sₓ)₂ where M=Mo, W, Ta, Zr, Co or Nb, x assuming arbitrary values from 0 to 1. Preferably, metal chalcogenides are selected from the group MoSe₂, WSe₂, TaSe₂, NbSe₂, Mo(Se₁₋ₓ,Sₓ)₂, W(Se₁₋ₓ,Sₓ)₂, Ta(Se₁₋ₓ,Sₓ)₂ and/or Nb(Se₁₋ₓ,Sₓ)₂, x assuming arbitrary values from 0 to 1.

Furthermore it is preferred that the metal of the first ply and the metal of the second ply of the contact layer correspond and/or the metal of the first ply and/or the metal of the second ply of the contact layer correspond to the metal of the bulk back electrode.

Back electrodes according to the present invention, in which the contact layer, the first ply, and/or the second ply of the contact layer has/have at least one dopant for a semiconductor absorber layer of a thin-film solar cell, in particular at least one element selected from the group sodium, potassium, and lithium and/or at least one compound of these elements, preferably with oxygen, selenium, sulfur, boron, and/or halogens, for example, iodine or fluorine, and/or at least one alkali metal bronze, in particular sodium and/or potassium bronze, preferably with a metal selected from molybdenum, tungsten, tantalum, and/or niobium, are also of particular advantage. Suitable bronzes include mixed oxides or mixtures of mixed oxides and oxides, for example, NaMoO₂+WO. The doped contact layer is obtainable, for example, by applying the metal chalcogenide, which is admixed with the dopant, in the metal chalcogenide source.

Within the meaning of the present invention, it is preferably provided that the average thickness of the bulk back electrode layer is in the range of 50 nm to 500 nm, in particular in the range of 80 nm to 250 nm, and/or that the average thickness of the barrier layer is in the range of 10 nm to 250 nm, in particular in the range of 20 nm to 150 nm, and/or that the average thickness of the contact layer is in the range of 2 nm to 200 nm, in particular in the range of 5 nm to 100 nm. The total thickness of the multilayer back electrode is preferably to be set in such a way that the specific total resistance of the back electrode according to the present invention does not exceed 50 microohms*cm, preferably 10 microohms*cm. Ohmic losses in a module connected in series may be reduced once again under these specifications.

In one particularly advantageous embodiment it is provided that the bulk back electrode layer contains molybdenum and/or tungsten, in particular molybdenum, or is essentially formed from molybdenum and/or tungsten, in particular molybdenum, the conductive barrier layer contains TiN or is essentially formed from TiN, and the contact layer, which contains dopant(s) in particular, contains MoSe₂ or is essentially formed from MoSe₂.

It has proven to be particularly suitable if the dopant, in particular sodium ions, is present in the contact layer and/or in the semiconductor absorber layer of the thin-film solar cell or the solar module having the back electrode in a dose in the range of 10¹³ to 10¹⁷ atoms/cm², preferably in a dose in the range of 10¹⁴ to 10¹⁶ atoms/cm².

For the case of the doping of the contact layer using dopants for the semiconductor absorber layer of a thin-film solar cell, the multilayer back electrode according to the present invention has proven itself. During the manufacture of the semiconductor absorber layer, temperatures greater than 300° C. or greater than 350° C. are regularly used. These temperatures are frequently also in the range of 500° C. to 600° C. At such temperatures dopants, such as sodium ions or sodium compounds in particular, migrate, in particular diffuse, out of the doped contact layer into the semiconductor absorber layer. A migration or diffusion into the back electrode layer does not occur due to the barrier layer.

Due to the mentioned relatively high temperatures during the processing of the semiconductor, it is advantageous for the selected layers of the multilayer back electrode, in particular the bulk back electrode and/or the conductive barrier layer, to be composed in such a way that their linear thermal coefficients of expansion are adapted to those of the semiconductor absorber and/or the substrate. Therefore, in particular the bulk back electrode and/or the barrier layer of the thin-film solar cells and solar modules according to the present invention should preferably be composed in such a way that a linear thermal coefficient of expansion of 14*10⁻⁶ K, preferably of 9*10⁻⁶ K, is not exceeded.

The object on which the present invention is based is also achieved by photovoltaic thin-film solar cells and photovoltaic thin-film solar modules, containing the multilayer back electrode according to the present invention.

In one preferred embodiment the thin-film solar cell according to the present invention includes, in this sequence, at least one substrate layer, at least one back electrode layer according to the present invention, at least one conductive barrier layer, at least one semiconductor absorber layer, which presses directly against the contact layer in particular, in particular a chalcopyrite or kesterite semiconductor absorber layer, and at least one front electrode.

Here such thin-film solar cells and solar modules are advantageous, in which at least one buffer layer (also called first buffer layer), in particular at least one layer containing or essentially formed of CdS or a CdS-free layer, in particular containing or essentially made of Zn(S,OH) or In₂S₃, and/or at least one layer (also called second buffer layer), containing and essentially formed of intrinsic zinc oxide and/or high-resistance zinc oxide, is provided between the semiconductor absorber layer and the front electrode.

Thin-film solar cells according to the present invention in which the semiconductor absorber layer may represent or include a quaternary IB-IIIA-VIA chalcopyrite layer, in particular a Cu(In,Ga)Se₂-layer, a penternary IB-IIIA-VIA chalcopyrite layer, in particular a Cu(In,Ga)(Se₁₋ₓSₓ)₂-layer, or a kesterite layer, in particular a Cu₂ZnSn(Seₓ,S₁₋ₓ)₄-layer, x assuming values from 0 to 1, have also proven to be particularly advantageous. The kesterite layers are generally based on an IB-IIA-IVA-VIA structure. Cu₂ZnSnSe₄ and Cu₂ZnSnS₄ are mentioned as examples.

The average thickness of the semiconductor absorber layer is usually within the range of 400 nm to 2500 nm, especially within the range of 500 nm to 1500 nm, and preferably in the range of 800 to 1200 nm.

Photovoltaic thin-film solar modules according to the present invention preferably include at least two, in particular a plurality, of in particular monolithically integrated thin-film solar cells according to the present invention connected in series. For example, 20 to 150 or 50 to 100 thin-film solar cells according to the present invention connected in series may be provided in a thin-film solar module according to the present invention.

The specific total resistance of the multilayer back electrode according to the present invention, in one suitable embodiment, should preferably not be greater than 50 microohms*cm, preferably 10 microohms*cm. In this way, a preferably low-loss monolithically integrated series circuit is to be ensured.

The object on which the present invention is based is furthermore achieved by a method for manufacturing a photovoltaic thin-film solar cell according to the present invention or a photovoltaic thin-film solar module according to the present invention, including the following steps: applying the bulk back electrode layer, the barrier layer, the contact layer, the metals of the semiconductor absorber layer, and/or the dopant(s) with the aid of physical thin-film deposition methods, in particular including physical vapor deposition (PVD) coating, vapor deposition with the aid of an electron beam vaporizer, vapor deposition with the aid of a resistance vaporizer, induction vaporization, ARC vaporization, and/or sputtering (sputter coating), in particular DC or RF magnetron sputtering, in each case preferably in a high vacuum, or with the aid of chemical gas phase deposition, in particular including chemical vapor deposition (CVD), low-pressure CVD, and/or atmospheric pressure CVD.

Here such an embodiment is advantageous, in which the bulk back electrode layer, the barrier layer, the contact layer, the metals of the semiconductor absorber layer, and/or the dopant(s) are applied with the aid of sputtering (sputter coating), in particular DC magnetron sputtering.

Furthermore, it may be provided that the dopants are applied together with at least one component of the contact layer and/or the absorber layer, in particular from a common mixed or sintered target, is also advantageous. Finally, it has also proven advantageous that the mixed or sintered target contain at least one dopant, selected from a sodium compound, a sodium-molybdenum bronze, and a sodium-tungsten bronze, in particular in a matrix component, selected from MoSe₂, WSe₂, Mo, W, copper, and/or gallium. For example, a molybdenum selenide target may be admixed with sodium sulfite or sodium sulfide as a dopant.

The present invention is accompanied by the surprising finding that with the structure of the multilayer back electrode according to the present invention, relatively thin layer thicknesses of the semiconductor absorber layer may be implemented in thin-film solar cells or solar modules, without efficiency losses having to be accepted. Higher efficiencies even frequently result using the systems according to the present invention. In this regard, it has been found that the barrier layers reflecting the sunlight contribute to further power generation. The sunlight passes the semiconductor absorber layer twice here. Furthermore, it has surprisingly been found that an improved effect also accompanies the fact that the semiconductor absorber layer, for example, based on a chalcopyrite or kesterite system, is deposited directly onto a molybdenum contact layer. This may react in this case in the subsequent semiconductor formation process at the interface to molybdenum selenide or sulfoselenide. Furthermore, it has surprisingly been found that dopants for the semiconductor absorber layer, for example, based on sodium, when well dosed over the contact layer, i.e., originally provided in the contact layer, introduce themselves into the mentioned semiconductor absorber layer. The temperatures during the formation of the semiconductor absorber layer are already sufficient for this purpose, the barrier layer also influencing the travel direction of the dopants in the direction of the semiconductor absorber layer in an assisting way. The mentioned dopants, as soon as they are provided in the semiconductor absorber layer, generally contribute to increasing the efficiency of a thin-film solar cell or solar module. In this case, it has proven to be advantageous that via the introduction via the contact layer, the amount of dopant which is finally provided in the finished product in the semiconductor absorber layer may be set very precisely. A reproducible increase of the efficiency independently of the composition of the glass and/or the bulk back electrode is first achieved in this way. Using the systems according to the present invention, surprisingly, efficiency losses due to uncontrolled reactions of the chalcogen, in particular selenium, during the formation of the semiconductor absorber layer with the bulk back electrode may also be avoided. Because a formation of metal chalcogenides, such as molybdenum selenide, no longer occurs on the surface of the bulk back electrode, a loss of conductivity of the bulk back electrode and a lateral inhomogeneous chalcogenide formation are also avoided and therefore the formation of microcracks is suppressed. This is because a significant volume expansion frequently accompanies the chalcogenide formation. Using the systems according to the present invention it is possible, for example, to set the thickness of the individual layers and also the thickness of the overall system more precisely and reliably than in conventional thin-film systems. At the same time, the multilayer back electrodes according to the present invention enable the use of contaminated bulk back electrode material, without the efficiency of the thin-film solar cell being disadvantageously influenced. The overall costs of a thin-film solar module may be significantly reduced in this way. Furthermore, a substantially more controlled buildup of the semiconductor absorber layer is carried out using the multilayer back electrodes according to the present invention. Components of the semiconductor such as Cu, In, and/or Ga no longer migrate into the back electrode, whereby the desired mass ratio of the components forming the semiconductor absorber layer may be set more intentionally and may also be maintained.

Further features and advantages of the present invention result from the following description, in which preferred specific embodiments of the present invention are explained as examples on the basis of schematic drawings.

### BRIEF DESCRIPTION OF THE DRAWINGS

FIG. 1 shows a schematic cross-sectional view through a partial system of a thin-film solar cell, containing a first specific embodiment of a multilayer back electrode according to the present invention.

FIG. 2 shows a schematic cross-sectional view through a partial system of a thin-film solar cell, containing a second specific embodiment of a multilayer back electrode according to the present invention.

FIG. 3 shows a schematic cross-sectional view through a partial system of a thin-film solar cell, containing a third specific embodiment of a multilayer back electrode according to the present invention.

### DETAILED DESCRIPTION OF THE INVENTION

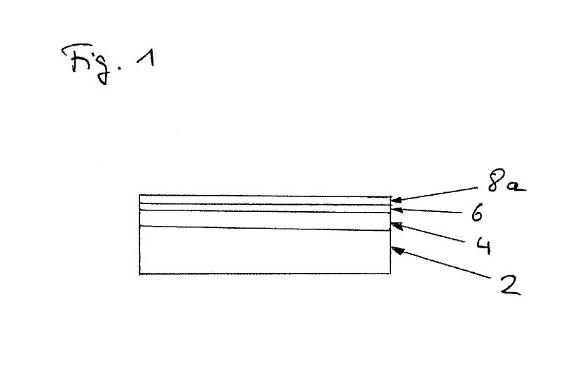

In the specific embodiment shown in FIG. 1 of a multilayer back electrode 1 according to the present invention, a bulk back electrode layer 4 made of molybdenum is provided on a substrate layer 2, for example, a glass substrate. A bidirectionally acting conductive barrier layer 6 is located applied thereon, made, for example, of tungsten nitride or titanium nitride, and adjacent to that layer an ohmic contact layer 8a made of metal chalcogenides, such as molybdenum selenide. Contact layer 8a may be admixed in a preferred specific embodiment with at least one dopant, for example, sodium ions or a sodium compound, in particular sodium sulfite or sodium sulfide.

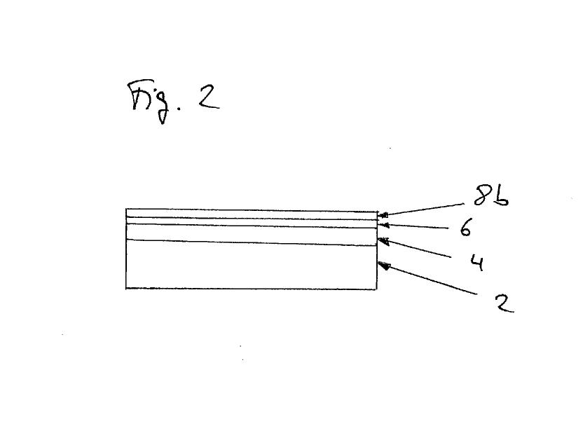

In the second specific embodiment of a multilayer electrode 1 according to the present invention shown in FIG. 2, the contact layer 8b represents a metal layer, for example a molybdenum layer or a tungsten layer, deviating from the embodiment shown in FIG. 1. This contact layer 8a may also be admixed in a preferred specific embodiment with at least one dopant, for example, sodium ions or a sodium compound, in particular sodium sulfite or sodium sulfide.

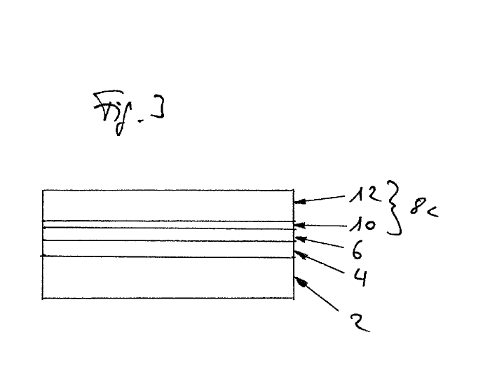

In the third specific embodiment of a multilayer electrode 1 according to the present invention shown in FIG. 3, contact layer 8c represents a two-layer system made of a first ply 10 made of a metal, for example, molybdenum or tungsten, which is adjacent to barrier layer 6 or adjoining thereon, and a second ply 12 made of a metal chalcogenide, for example, molybdenum selenide and/or tungsten selenide, which adjoins first ply 10 and is thus not adjacent to barrier layer 6. At least one dopant, for example, sodium ions or a sodium compound, in particular sodium sulfite or sodium sulfide, is preferably also provided in contact layer 8c in this specific embodiment. In this case, the dopant may be present in the first ply and/or the second ply.

1-22. (canceled)

23. A multilayer back electrode for a photovoltaic thin-film solar cell, comprising in the following sequence:
at least one bulk back electrode layer containing at least one of V, Mn, Cr, Mo, Co, Zr, Ta, Nb, and W;
at least one conductive barrier layer; and
at least one ohmic contact layer containing (i) at least one first ply adjacent to the at least one conductive barrier layer, wherein the at least one first ply contains at least one of Mo, W, Ta, Nb, Zr and Co, and (ii) at least one second ply not adjacent to the at least one barrier layer, wherein the at least one second ply contains at least one metal chalcogenide.

24. The back electrode as recited in claim 23, wherein the at least one bulk back electrode and the at least one contact layer each contain one of molybdenum or tungsten.

25. The back electrode as recited in claim 23, wherein the at least one conductive barrier layer represents a barrier for components which diffuse at least one of (i) out of the at least one bulk back electrode layer, (ii) via the bulk back electrode layer, (iii) out of the at least one ohmic contact layer, and (iv) via the at least one ohmic contact layer.

26. The back electrode as recited in claim 25, wherein the at least one conductive barrier layer represents a barrier for alkali ions.

27. The back electrode as recited in claim 25, wherein the at least one conductive barrier layer contains at least one of a metal nitride, a metal carbide, a metal boride, and a metal silicon nitride.

28. The back electrode as recited in claim 25, wherein the at least one bulk back electrode layer is contaminated with one of Fe, Ni, Ti, Zr, Hf, V, Nb, Ta, W, Al, or Na.

29. The back electrode as recited in claim 25, wherein the metal component of the metal chalcogenide of the second ply of the at least one ohmic contact layer includes at least one of molybdenum, tungsten, tantalum, zirconium, cobalt and niobium, and the chalcogenide component of the metal chalcogenide includes at least one of selenium and sulfur.

30. The back electrode as recited in claim 25, wherein at least one of (i) the metal of the first ply and the metal of the second ply of the at least one ohmic contact layer are identical, and (ii) the metal of the first ply and the metal of the second ply of the at least one ohmic contact layer correspond to the metal of the at least one bulk back electrode.

31. The back electrode as recited in claim 25, wherein the at least one ohmic contact layer has at least one dopant for a semiconductor absorber layer of a thin-film solar cell, the at least one dopant including at least one of sodium, potassium, and lithium.

32. The back electrode as recited in claim 25, wherein at least one of:
the average thickness of the at least one bulk back electrode layer is in the range of 80 nm to 250 nm; and
the at least one conductive barrier layer is in the range of 20 nm to 150 nm; and
the at least one ohmic contact layer is in the range of 5 nm to 100 nm.

33. The back electrode as recited in claim 31, wherein:
the at least one bulk back electrode layer contains at least one of molybdenum and tungsten;
the at least one conductive barrier layer contains TiN; and
the at least one contact layer contains MoSe₂.

34. The back electrode as recited in claim 31, wherein the dopant includes sodium ions which are provided in the contact layer in a dose in the range of 10¹³ to 10¹⁷ atoms/cm².

35. The back electrode as recited in claim 31, wherein the back electrode is part of a photovoltaic thin-film solar cell.

36. A photovoltaic thin-film solar module, comprising:
at least one photovoltaic thin-film solar cell including the following in sequence:
a substrate layer;
at least one bulk back electrode layer containing at least one of V, Mn, Cr, Mo, Co, Zr, Ta, Nb, and W;
at least one conductive barrier layer;
at least one ohmic contact layer containing (i) at least one first ply adjacent to the at least one conductive barrier layer, wherein the at least one first ply contains at least one of Mo, W, Ta, Nb, Zr and Co, and (ii) at least one second ply not adjacent to the at least one barrier layer, wherein the at least one second ply contains at least one metal chalcogenide;
at least one semiconductor absorber layer which presses directly against the at least one ohmic contact layer; and
at least one front electrode.

37. The thin-film solar module as recited in claim 36, wherein at least one of (i) a buffer layer containing one of Zn(S,OH) or In₂S₃, and (ii) at least one layer containing at least one of intrinsic zinc oxide and high-resistance zinc oxide, is provided between the semiconductor absorber layer and the front electrode of the at least one photovoltaic thin-film solar cell.

38. The thin-film solar module as recited in claim 36, wherein at least one of:
(i) the semiconductor absorber layer includes one of Cu(In,Ga)Se₂-layer, a Cu(In,Ga)(Se₁₋ₓ)₂-layer, or a Cu₂ZnSn(Seₓ,S₁₋ₓ)₄-layer, x assuming values from 0 to 1; and
(ii) the average thickness of the semiconductor absorber layer is in the range of 800 nm to 1200 nm.

39. The thin-film solar module as recited in claim 37, wherein at least two thin-film solar cells monolithically integrated and connected in series are provided.

40. A method for manufacturing photovoltaic thin-film solar cell which includes in sequence a substrate layer; at least one bulk back electrode layer containing at least one of V, Mn, Cr, Mo, Co, Zr, Ta, Nb, and W; at least one conductive barrier layer; at least one ohmic contact layer containing (i) at least one first ply adjacent to the at least one conductive barrier layer, wherein the at least one first ply contains at least one of Mo, W, Ta, Nb, Zr and Co, and (ii) at least one second ply not adjacent to the at least one barrier layer, wherein the at least one second ply contains at least one metal chalcogenide; at least one semiconductor absorber layer which presses directly against the at least one ohmic contact layer; and at least one front electrode, the method comprising:
applying the bulk back electrode layer, the barrier layer, the contact layer, metals of the semiconductor absorber layer, and the dopants with the aid of a physical thin-film deposition, wherein the dopants are applied together with at least one component of at least one of the ohmic contact layer and the semiconductor absorber layer.
